(19) United States
(12) Patent Application Publication
(10) Pub. No.: US 2026/0011055 A1
(43) Pub. Date: Jan. 8, 2026

(54) INFORMATION PROCESSING APPARATUS, INFORMATION PROCESSING METHOD, AND STORAGE MEDIUM

(71) Applicant: Tokyo Electron Limited, Tokyo (JP)

(72) Inventors: Ryota AOI, Hokkaido (JP); Nobutoshi TERASAWA, Hokkaido (JP); Shintaro SARUWATARI, Hokkaido (JP)

(21) Appl. No.: 19/255,528

(22) Filed: Jun. 30, 2025

(30) Foreign Application Priority Data
Jul. 8, 2024 (JP) 2024-109798

(51) Int. Cl. G06T 11/20; H01L 21/02

(52) U.S. Cl. CPC G06T 11/206; H01L 21/02

(57) ABSTRACT

An information processing apparatus includes: an acquisition unit that acquires sensor data including a first sensor value and a second sensor value measured in a substrate processing apparatus when the substrate processing apparatus is not executing a process; and a display unit that displays information representing a correlation between the first sensor value and the second sensor value.

### CROSS REFERENCES TO RELATED APPLICATIONS

This application is based on and claims priority from Japanese Patent Application No. 2024-109798, filed on Jul. 8, 2024, with the Japan Patent Office, the disclosure of which is incorporated herein in its entirety by reference.

### TECHNICAL FIELD

The present disclosure relates to an information processing apparatus, an information processing method, and a storage medium.

### BACKGROUND

A technology is known that analyzes time-series data of sensor values measured in a substrate processing apparatus. Japanese Patent Laid-Open Publication No. 2022-003664 discloses an information processing apparatus, which calculates a monitoring band used for a waveform monitoring method from sensor waveform data measured in a semiconductor manufacturing apparatus that is executing a process according to the same recipe, and monitors the waveform of the sensor waveform data using the monitoring band to detect an abnormality sign of the semiconductor manufacturing apparatus.

### SUMMARY

According to an aspect of the present disclosure, an information processing apparatus includes: an acquisition unit that acquires sensor data including a first sensor value and a second sensor value measured in a substrate processing apparatus when the substrate processing apparatus is not executing a process; and a display unit that displays information representing a correlation between the first sensor value and the second sensor value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block diagram illustrating an example of an overall configuration of a substrate processing system.

FIG. 2 is a cross-sectional view illustrating an example of a substrate processing apparatus.

FIG. 3 is a plan view illustrating an example of the substrate processing apparatus.

FIG. 4 is a block diagram illustrating an example of a hardware configuration of a computer.

FIG. 5 is a block diagram illustrating an example of a functional configuration of an analysis apparatus.

FIG. 6 is a view illustrating a first example of an analysis screen.

FIG. 7 is a view illustrating a second example of the analysis screen.

FIG. 8 is a view illustrating a third example of the analysis screen.

FIG. 9 is a flowchart illustrating an example of an analysis method.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In each drawing, the same components will be denoted with the same reference numerals, and overlapping descriptions thereof may be omitted.

### EMBODIMENTS

An embodiment of the present disclosure relates to a substrate processing system including a substrate processing apparatus that processes a substrate, which is an example of a workpiece. In the present embodiment, the substrate processing apparatus performs a heat treatment on a semiconductor wafer, which is an example of the substrate, in a processing container. The substrate processing system further includes an analysis apparatus that analyzes sensor data representing a sensor value measured by a sensor provided in the substrate processing apparatus.

In the substrate processing apparatus, one or more sensors are provided to measure the state of the substrate processing apparatus. When the substrate processing apparatus performs a process to process the substrate, the sensors provided in the substrate processing apparatus measure predetermined sensor values at predetermined time intervals. The time-series data of the sensor value measured by each sensor is stored in a storage device provided in the substrate processing apparatus or a storage device connected to the substrate processing apparatus via a network.

There is a technology that displays the sensor value in the time-series manner in order to analyze the state of the substrate processing apparatus. As an example, a technology is known that extracts a sensor value satisfying a predetermined monitoring condition, and displays waveform data representing a variation of the extracted sensor value over time. According to this technology, it is possible to analyze the long-term trend of the sensor value. However, the technology of the prior art has a difficulty in analyzing a relationship between a specific sensor value and another sensor value.

Meanwhile, there is a technology that displays a correlation graph of a plurality of sensor values in order to analyze the state of the substrate processing apparatus. As an example, a technology is known that displays a correlation graph between a sensor value measured during a period of time when a process recipe is being executed, and another sensor value. The correlation graph represents a correlation of the plurality of sensor values by plotting data including the plurality of sensor values in a low-dimensional space with the plurality of sensor values as axes, respectively. According to this technology, it is possible to analyze the relationship of the plurality of sensor values. However, since the technology of the prior art displays the correlation graph of the sensor values measured during the execution of a process, it is not possible to analyze the relationship of the plurality of sensor values when a process is not executed.

The present embodiment analyzes the state of the substrate processing apparatus when a process is not being executed. The present embodiment acquires sensor data including a first sensor value and a second sensor value measured in a substrate processing apparatus when the substrate processing apparatus is not executing a process, and displays information representing a correlation between the first sensor value and the second sensor value.

In an aspect, the present embodiment displays the information representing the correlation between the first sensor value and the second sensor value measured when a process is not being executed, so that the state of the substrate processing apparatus when a process is not being executed may be analyzed.

### <System Configuration>

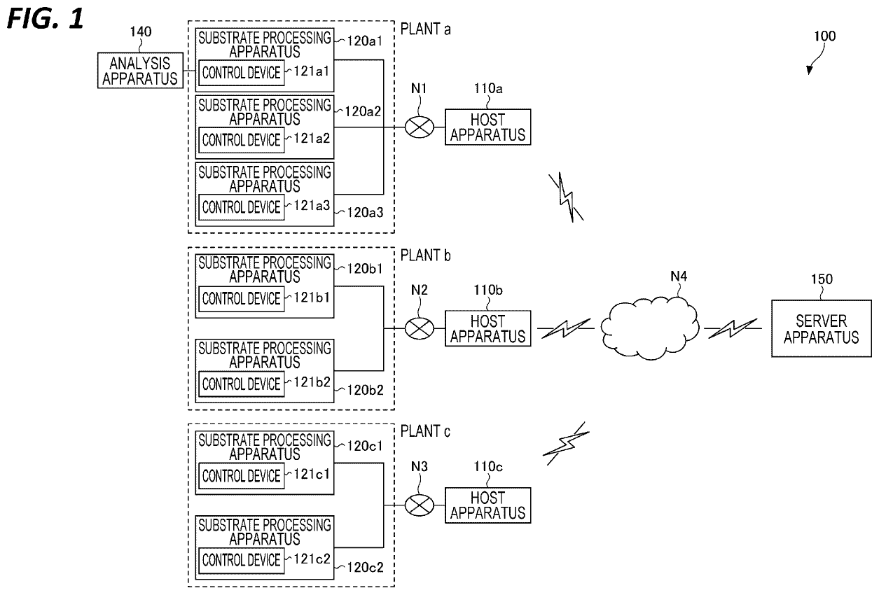

The overall configuration of a substrate processing system according to the present embodiment will be described with reference to FIG. 1. FIG. 1 is a block diagram illustrating an example of the overall configuration of the substrate processing system.

As illustrated in FIG. 1, a substrate processing system 100 includes substrate processing apparatuses 120a1 to 120a3 and control devices 121a1 to 121a3 in a plant “a.” The substrate processing apparatuses 120a1 to 120a3 and the control devices 121al to 121a3 are connected to each other by a wired or wireless method.

The substrate processing system 100 further includes substrate processing apparatuses 120b1 and 120b2 and control devices 121b1 and 121b2 in a plant “b.” The substrate processing apparatuses 120b1 and 120b2 and the control devices 121b1 and 121b2 are connected to each other by a wired or wireless method.

The substrate processing system 100 further includes substrate processing apparatuses 120c1 and 120c2 and control devices 121c1 and 121c2 in a plant “c”. The substrate processing apparatuses 120c1 and 120c2 and the control devices 121cl and 121c2 are connected to each other by a wired or wireless method.

The substrate processing apparatuses 120a1 to 120a3, the substrate processing apparatuses 120b1 and 120b2, and the substrate processing apparatuses 120c1 and 120c2 are connected to host apparatuses 110a, 110b, and 110c via networks N1 to N3, respectively. Each substrate processing apparatus performs a substrate processing under the control of each control device based on an instruction from each of the host apparatuses 110a, 110b, and 110c. The host apparatuses 110a, 110b, and 110c are connected to a server apparatus 150 via a network N4 such as the Internet.

In the descriptions herein below, the substrate processing apparatuses 120al to 120a3, 120b1, 120b2, 120c1, and 120c2 will be collectively referred to as a substrate processing apparatus 120. Further, the control devices 121a1 to 121a3, 121b1, 121b2, 121c1, and 121c2 will be collectively referred to as a control device 121. The host apparatuses 110a, 110b, and 110c will be collectively referred to as a host device 110.

It is assumed that each of the substrate processing apparatuses 120a1 to 120a3, 120b1, 120b2, 120c1, and 120c2 accumulates various types of data in its own device and manages the data.

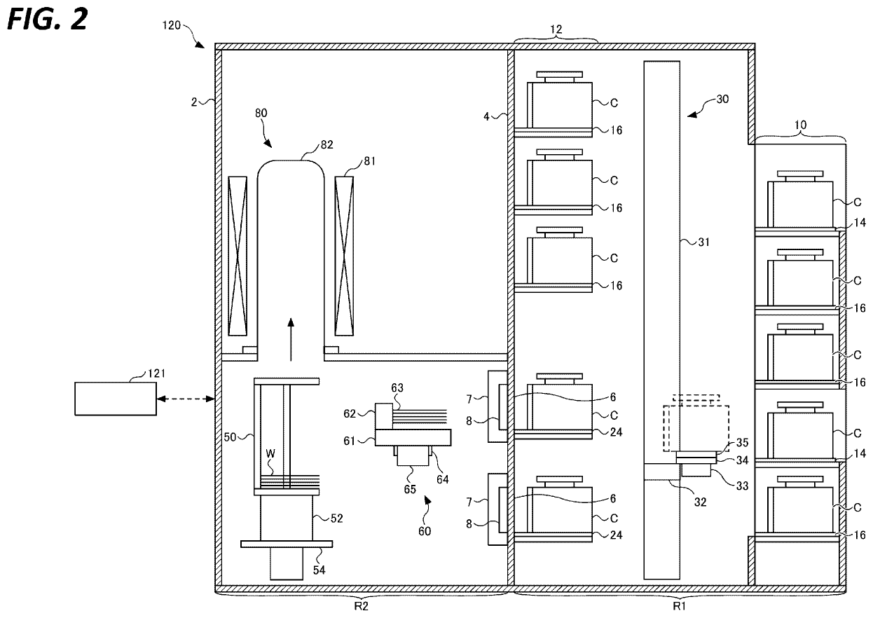

An analysis apparatus 140 is connected to the substrate processing apparatus 120 including the substrate processing apparatus 120al, to continuously acquire the data accumulated in each substrate processing apparatus 120. While the example in FIG. 2 represents a state where the analysis apparatus 140 is connected to the substrate processing apparatus 120a1, the present disclosure is not limited thereto. In the present embodiment, descriptions will be made on details of the case where the analysis apparatus 140 is connected to the substrate processing apparatus 120a1.

The substrate processing system 100 illustrated in FIG. 1 is merely an example, and various examples of the system configuration are conceivable according to applications or purposes. The device classification in FIG. 1 such as the host device 110, the substrate processing apparatus 120, the analysis apparatus 140, and the server apparatus 150 is merely an example. For example, the number of plants, the number of host apparatuses 110, the number of substrate processing apparatuses 120, the number of control devices 121, and the number of analysis apparatuses 140 are merely examples, and the present disclosure is not limited thereto.

For example, the substrate processing system 100 may be configured in various forms, such as an integrated configuration of at least two of the host device 110, the substrate processing apparatus 120, the control device 121, the analysis apparatus 140, and the server apparatus 150 and a configuration in which these devices are further divided. For example, the control device 121 may control a plurality of substrate processing apparatuses 120 collectively, may be provided for each substrate processing apparatus 120 on a one-to-one basis, or may be integrated with the substrate processing apparatus 120.

The analysis apparatus 140 may be implemented by the host device 110 or the server apparatus 150. In this case, the analysis apparatus 140 is unnecessary. Further, the analysis apparatus 140 may be implemented by the control device 121. The analysis apparatus 140 may be implemented by a control device that controls a plurality of control devices 121 collectively.

### <Substrate Processing Apparatus>

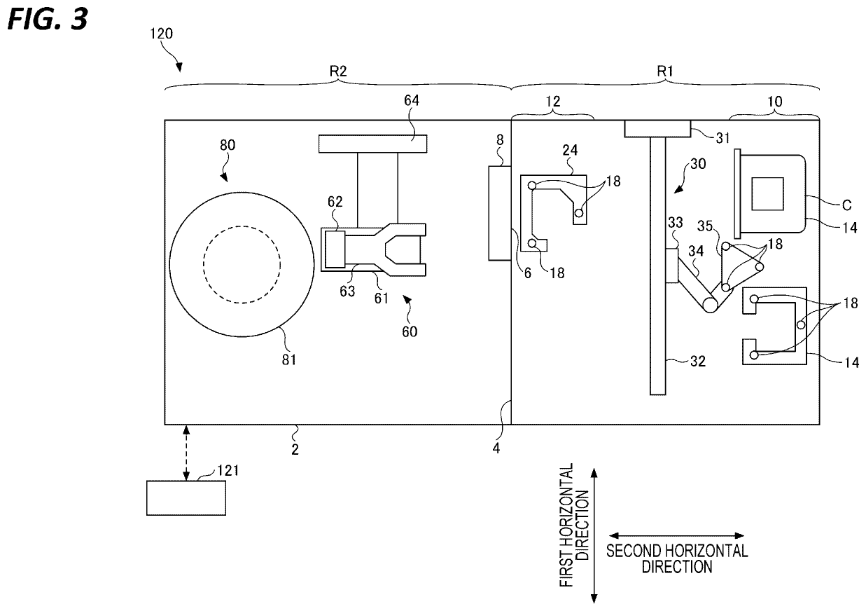

An example of the substrate processing apparatus according to the present embodiment will be described with reference to FIGS. 2 and 3. FIG. 2 is a cross-sectional view illustrating an example of the substrate processing apparatus. FIG. 3 is a plan view illustrating an example of the substrate processing apparatus.

FIGS. 2 and 3 illustrate a vertical-type heat treatment apparatus 120, which is an example of the substrate processing apparatus. The vertical-type heat treatment apparatus 120 is a substrate processing apparatus that accommodates a plurality of semiconductor wafers W, which is an example of workpieces, at a time to perform a heat treatment such as oxidation, diffusion, or low-pressure chemical vapor deposition (CVD) on the wafers W.

The substrate processing apparatus 120 is configured by being accommodated in a housing 2 that makes up the exterior of the apparatus. A carrier transfer region R1 and a wafer transfer region R2 are formed in the housing 2. The carrier transfer region R1 and the wafer transfer region R2 are separated by a partition wall 4. A transfer port 6 is formed in the partition wall 4 to communicate the carrier transfer region R1 and the wafer transfer region R2 with each other, and to transfer the wafer W therethrough. The transfer port 6 is opened and closed by a door mechanism 8 that conforms to the front-opening interface mechanical standard (FIMS). A drive mechanism of a lid opening/closing device 7 is connected to the door mechanism 8, and the door mechanism 8 is movable in the front-back direction and the vertical direction by the drive mechanism to open and close the transfer port 6.

Hereafter, the arrangement direction of the carrier transfer region R1 and the wafer transfer region R2 will be referred to as the front-back direction (corresponding to a second horizontal direction in FIG. 3), and the horizontal direction perpendicular to the front-back direction will be referred to as the left-right direction (corresponding to a first horizontal direction in FIG. 3).

The carrier transfer region R1 is a region under the air atmosphere. The carrier transfer region R1 is a region where a carrier C accommodating wafers W is transferred between components in the substrate processing apparatus 120, which will be described herein later, loaded into the substrate processing apparatus 120 from the outside, or unloaded from the substrate processing apparatus 120 to the outside. The carrier C may be, for example, a front-opening unified pod (FOUP). The cleanliness in the FOUP is maintained at a predetermined level, which may prevent the adhesion of foreign matter or the formation of a natural oxide film to/on the surface of wafers W. The carrier transfer region R1 includes a first transfer region 10 and a second transfer region 12 located at the rear side of the first transfer region 10 (on the side of the wafer transfer region R2).

In the first transfer region 10, for example, load ports 14 are provided in two vertical tiers (see FIG. 2), and further, two load ports 14 are provided on the left and right sides of each tier (see FIG. 3). Each load port 14 is a carry-in placement stage that receives a carrier C when the carrier C is loaded into the substrate processing apparatus 120. The load ports 14 are provided at a location where the wall of the housing 2 is open, which allows the access to the substrate processing apparatus 120 from the outside. For example, by a transfer device (not illustrated) provided outside the substrate processing apparatus 120, carriers C may be loaded into and placed in the load ports 14, and may be unloaded from the load ports 14 to the outside. Further, for example, since the load ports 14 are provided in two tiers in the vertical direction, the carriers C may be loaded and unloaded at both levels. A stocker 16 may be provided below each load port 14 to store a carrier C. On the surface of the load port 14 for placing a carrier C, positioning pins 18 are provided, for example, at three locations to position the carrier C. The load port 14 may be configured to be movable in the front-back direction in the state where the carrier C is placed on the load port 14.

In the lower part of the second transfer region R2, two FIMS ports 24 (see, e.g., FIG. 2) are disposed to be arranged in the vertical direction. The FIMS ports 24 are each a holding stage that holds a carrier C when the wafers W in the carrier C are carried into/out of a heat treatment furnace 80 to be described herein later in the wafer transfer region R2. The FIMS ports 24 are configured to be movable in the front-back direction. The positioning pins 18 are also provided at three locations on the surface of each FIMS port 24 where the carrier C is placed, to position the carrier C, as in the load port 14.

In the upper part of the second transfer region 12, stockers 16 are provided to store carriers C. The stockers 16 are configured with, for example, three shelves, and two or more carriers C may be placed on each shelf in the left-right direction. The stockers 16 may be further disposed in the lower part of the second transfer region 12 where no carrier placement stage is provided.

A carrier transfer mechanism 30 is provided between the first transfer region 10 and the second transfer region 12, to transfer carriers C among the load ports 14, the stockers 16, and the FIMS ports 24.

The carrier transfer mechanism 30 includes a first guide 31, a second guide 32, a moving unit 33, an arm unit 34, and a hand unit 35. The first guide 31 is configured to extend in the vertical direction. The second guide 32 is connected to the first guide 31, and configured to extend in the left-right direction (the first horizontal direction). The moving unit 33 is configured to move in the left-right direction while being guided by the second guide 32. The arm unit 34 includes one joint and two arms, and is provided on the moving unit 33. The hand unit 35 is provided at the tip of the arm unit 34. In the hand unit 35, pins 18 are provided at three locations to position a carrier C.

The wafer transfer region R2 is a region where the wafers W are taken out from the carrier C, and various types of processing are performed on the wafers W. The wafer transfer region R2 has an inert gas atmosphere, for example, a nitrogen (N₂) gas atmosphere, to prevent the formation of oxide film on the wafers W. In the wafer transfer region R2, a vertical-type heat treatment furnace 80 is provided with its lower end opened as a furnace port.

The heat treatment furnace 80 may accommodate the wafers W, and includes a cylindrical processing container 82 made of quartz to perform a heat treatment on the wafers W. A cylindrical heater 81 is disposed around the processing container 82, and the heat treatment of the accommodated wafers W is performed by the heating of the heater 81. A shutter (not illustrated) is provided below the processing container 82. The shutter is a door to cover the lower end of the heat treatment furnace 80 during a period of time from the unload of a wafer boat 50 from the heat treatment furnace 80 and the load-in of the next wafer boat 50. Below the heat treatment furnace 80, the wafer boat 50, which is a substrate holder, is disposed on a lid 54 via a heat insulation tube 52. In other words, the lid 54 is provided below the wafer boat 50 in an integrated form with the wafer boat 50.

The wafer boat 50 is made of, for example, quartz, and configured to hold the wafers W with a large diameter (e.g., 300 mm or 450 mm in diameter) substantially horizontally at predetermined intervals in the vertical direction. The number of wafers W accommodated in the wafer boat 50 is not particularly limited, but may be, for example, 50 to 200. The lid 54 is supported by a lifting mechanism (not illustrated), and the wafer boat 50 is loaded into and unloaded from the heat treatment furnace 80 by the lifting mechanism. A wafer transfer device 60 is provided between the wafer boat 50 and the transfer port 6.

The wafer transfer device 60 transfers the wafers W between the carrier C held on the FIMS port 24 and the wafer boat 50. The wafer transfer device 60 includes a guide mechanism 61, a moving body 62, a fork 63, a lifting mechanism 64, and a rotation mechanism 65. The guide mechanism 61 has a rectangular shape. The guide mechanism 61 is attached to the lifting mechanism 64 that extends in the vertical direction, and configured to be movable in the vertical direction by the lifting mechanism 64 and rotatable by the rotation mechanism 65. The moving body 62 is provided to be movable on the guide mechanism 61 along the longitudinal direction of the guide mechanism 61. The fork 63 is a transfer device attached via the moving body 62, and a plurality of forks (e.g., five forks) is provided. Since a plurality of wafers W may be transferred simultaneously by the plurality of forks 63, the time required for transferring the wafers W may be reduced. Meanwhile, a single fork 63 may be provided.

A filter unit (not illustrated) may be provided in the ceiling or the side wall of the wafer transfer region R2. The filter unit may be, for example, a high efficiency particulate air (HEPA) filter or an ultra-low penetration air (ULPA) filter. By providing the filter unit, clean air may be supplied into the wafer transfer region R2.

### <Computer>

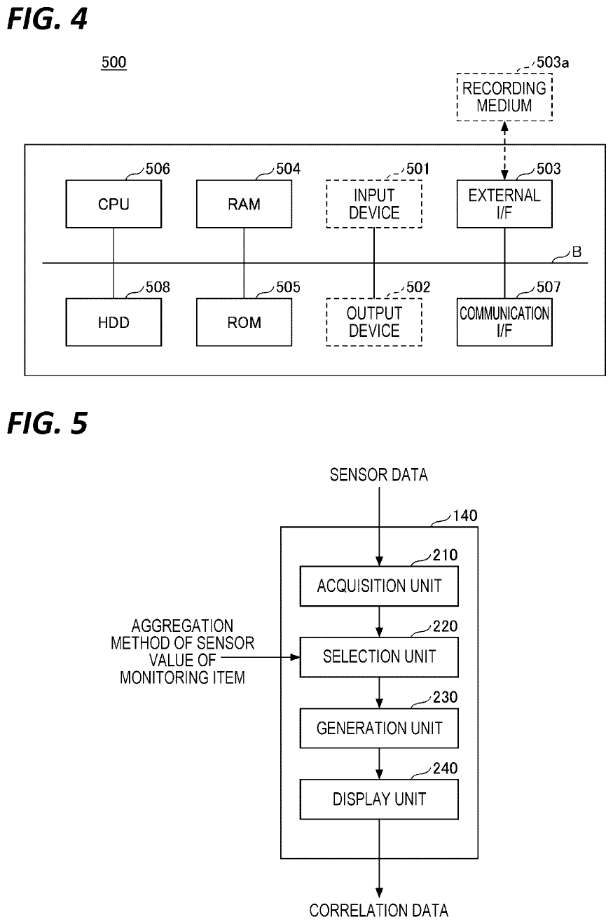

The host device 110, the control device 121, the analysis apparatus 140, and the server apparatus 150 included in the substrate processing system 100 illustrated in FIG. 1 are implemented by, for example, a computer with the hardware configuration illustrated in FIG. 4. FIG. 4 is a block diagram illustrating an example of the hardware configuration of the computer.

As illustrated in FIG. 4, a computer 500 includes, for example, an input device 501, an output device 502, an external I/F 503, a random access memory (RAM) 504, a read only memory (ROM) 505, a central processing unit (CPU) 506, a communication I/F 507, and a hard disk drive (HDD) 508, which are connected to each other via a bus B. The input device 501 and the output device 502 may be connected and used when necessary.

The input device 501 is, for example, a keyboard, a mouse, or a touch panel, and is used by, for example, an operator to input each operation signal. The output device 502 is, for example, a display, and displays a result of a process executed by the computer 500. The communication I/F 507 is provided to connect the computer 500 to a network. The HDD 508 is an example of a nonvolatile storage device that stores programs and data.

The external I/F 503 is an interface to an external device. The computer 500 may perform a read from and/or a write to a record medium 503a, such as a secure digital (SD) memory card, via the external I/F 503. The ROM 505 is an example of a nonvolatile semiconductor memory (storage device) that stores programs and data. The RAM 504 is an example of a volatile semiconductor memory (storage device) that temporarily stores programs and data.

The CPU 506 is a computing device that reads programs and data from the storage device such as the ROM 505 or the HDD 508 onto the RAM 504, and executes a process to implement the control or function of the entire computer 500.

### <Functional Configuration>

The functional configuration of the analysis apparatus 140 will be described with reference to FIG. 5. FIG. 5 is a block diagram illustrating an example of the functional configuration of the analysis apparatus.

As illustrated in FIG. 5, the analysis apparatus 140 includes an acquisition unit 210, a selection unit 220, a generation unit 230, and a display unit 240. The analysis apparatus 140 functions as the acquisition unit 210, the selection unit 220, the generation unit 230, and the display unit 240 when an analysis program installed in advance is executed.

For example, the acquisition unit 210, the selection unit 220, the generation unit 230, and the display unit 240 are implemented in the manner that the CPU 506 illustrated in FIG. 3 executes the analysis program loaded onto the RAM 504.

The acquisition unit 210 acquires sensor data generated in the substrate processing apparatus 120. The sensor data is time-series data representing a sensor value measured by a sensor provided in the substrate processing apparatus 120. In the present embodiment, the sensor data includes two or more time-series data measured by two or more sensors, respectively, provided in the substrate processing apparatus 120.

The sensor data may include a sensor value measured during a process execution period and a sensor value measured outside the process execution period. The “process execution period” refers to a time interval during which the substrate processing apparatus 120 is executing a process of processing a workpiece. The “outside the process execution period” refers to a time interval during which the substrate processing apparatus 120 is not executing the process of processing the workpiece, and a time interval outside the process execution period.

The process may include at least one step. The sensor data may include a single time-series data recorded by executing the process multiple times or a plurality of time-series data recorded at each process or step, for each sensor provided in the substrate processing apparatus 120.

In the present embodiment, the sensor data may include, for example, the power of the heater 81 that heats the processing container 82, and the temperature in the processing container 82. The heater 81 heats the processing container 82 to maintain the temperature in the processing container 82 at a constant temperature even outside the process execution period, in order to prevent the liquefaction of a gas in the processing container 82. Further, there is a case where the heater 81 is attached or detached due to, for example, the maintenance of the substrate processing apparatus 120. The power of the heater 81 and the temperature in the processing container 82 have a specific relationship. By analyzing the relationship between the power of the heater 81 and the temperature in the processing container 82 outside the process execution period, it is possible to detect, for example, the attachment failure of the heater or the deterioration of the heater.

In the present embodiment, the sensor data may include, for example, the flow rate of a purge gas introduced into the wafer transfer region R2 where the wafers W are transferred to the processing container 82, and the pressure in the wafer transfer region R2. The transfer port 6, through which the carrier C accommodating the wafers W is transferred to the wafer transfer region R2, is opened and closed by the door mechanism 8 that conforms to the FIMS standard. The flow rate of the purge gas introduced into the wafer transfer region R2 and the pressure in the wafer transfer region R2 have a specific relationship, but the pressure in the wafer transfer region R2 decreases when the degree of airtightness of the transfer port 6 decreases. Since the purge gas is introduced into the wafer transfer region R2 before and after the execution of the process, the relationship between the flow rate of gas and the pressure in the wafer transfer region R2 may not be accurately analyzed even by using the sensor data measured during the process execution period. By analyzing the relationship between the flow rate of gas and the pressure in the wafer transfer region R2 outside the process execution period, it is possible to detect, for example, the necessity for adjustment or repair of the door mechanism 8.

The selection unit 220 selects sensor data including a first sensor value and sensor data indicating a second sensor value from the sensor data acquired by the acquisition unit 210. The selection unit 220 may select sensor data including a first sensor value or a second sensor value designated by a user of the analysis apparatus 140.

The selection unit 220 may select sensor data satisfying a predetermined monitoring condition. The monitoring condition may include a condition for the first sensor value. The monitoring condition may include an aggregation method for the first sensor value. A plurality of monitoring conditions may be predetermined. The monitoring condition may be designated by the user of the analysis apparatus 140. The selection unit 220 may select sensor data satisfying one monitoring condition selected by the user of the analysis apparatus 140 from the plurality of monitoring conditions.

The selection unit 220 may select an aggregation method for the second sensor value. The selection unit 220 may select an aggregation method selected by the user of the analysis apparatus 140 from a plurality of predetermined aggregation methods. The aggregation method may be a method of aggregating a representative value from a plurality of sensor values included in a predetermined time unit. The aggregation method may include, for example, at least one of a start point, an end point, a maximum value, a minimum value, an average value, and a standard deviation. The start point refers to the first value of time-series data corresponding to each time unit. The end point refers to the last value of time-series data corresponding to each time unit. The average value may be, for example, an arithmetic mean. The standard deviation may be, for example, 3σ.

The generation unit 230 generates correlation data representing the correlation between the first sensor value and the second sensor value selected by the selection unit 220. The correlation data may include a correlation graph. The generation unit 230 may generate the correlation graph by plotting the sensor data in a plane with axes representing the first sensor value and the second sensor value (i.e., a two-dimensional space).

The correlation data may include an evaluation index based on the correlation graph. The evaluation index may include an approximate straight line of the correlation graph. The evaluation index may include a correlation coefficient or a determination coefficient of the correlation graph. The evaluation index may include any index as long as it indicates the accuracy of the approximate straight line.

When plotting the sensor data, the generation unit 230 may calculate a representative value in a predetermined time unit for each sensor value. The predetermined time unit may be a time interval divided with a predetermined time length. The predetermined time length may be determined, for example, in units of seconds, minutes, hours, or days. The predetermined time unit may be, for example, a time interval during which one process or step is executed, within the process execution period.

The generation unit 230 may calculate the representative value of the first sensor value using the aggregation method determined according to the monitoring condition. The generation unit 230 may calculate the representative value of the second sensor value using the aggregation method selected by the selection unit 220.

The display unit 240 displays the correlation data generated by the generation unit 230. The display unit 240 may display an analysis screen including the correlation data on a display, which is an example of the output device 502. The display unit 240 may transmit the screen data including the correlation data to another information processing device such as the control device 121, the host device or the server apparatus, and display the analysis screen on a display of the corresponding information processing device.

The analysis screen may display the correlation graph between the first sensor value and the second sensor value. The analysis screen may display the evaluation index of the correlation graph along with the correlation graph. The analysis screen may display at least one of the first sensor value and the second sensor value for each plot, on the correlation graph. The analysis screen may display a time-series graph representing a waveform of the first sensor value or the second sensor value. The time-series graph is a graph representing a variation of a sensor value over time by plotting the sensor value in a low-dimensional space (e.g., a plane) with axes representing the sensor value and time.

The analysis screen may include a screen component for selecting at least one of analysis conditions. The analysis conditions may include, for example, at least one of a monitoring item, the second sensor value, and the aggregation method of the second sensor value. The monitoring item is an item for selecting the first sensor value corresponding to a predetermined monitoring condition. For example, the analysis screen may include a display area that displays the monitoring item in a selectable manner. For example, the analysis screen may include a display area that displays the second sensor value and the aggregation method thereof in a selectable manner. For example, the analysis screen may include a selection area that allows the selection of the second sensor value and the aggregation method thereof.

The functional configuration of the analysis apparatus 140 illustrated in FIG. 5 is merely an example, and various examples of the functional configuration are conceivable according to applications or purposes. The classification of processing units such as the acquisition unit 210, the selection unit 220, the generation unit 230, and the display unit 240 illustrated in FIG. 5 is an example. For example, at least two of the acquisition unit 210, the selection unit 220, the generation unit 230, and the display unit 240 may be integrated into a single processing unit. For example, at least one of the acquisition unit 210, the selection unit 220, the generation unit 230, and the display unit 240 may be divided into a plurality of processing units.

### <Analysis Screen>

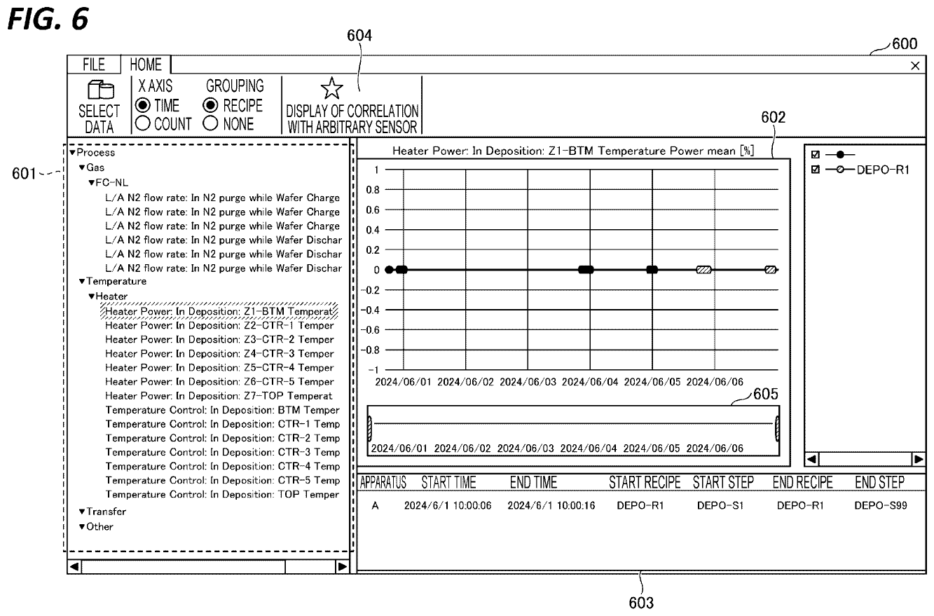

The analysis screen displayed by the analysis apparatus 140 will be described with reference to FIGS. 6 to 8.

FIG. 6 is a view illustrating a first example of the analysis screen. FIG. 6 illustrates an example of an analysis screen 600 that displays the time-series graph of the first sensor value corresponding to the monitoring item. As illustrated in FIG. 6, the analysis screen 600 includes a monitoring item selection section 601, a graph display section 602, a data display section 603, and a correlation display button 604.

The monitoring item selection section 601 displays a list of monitoring items in a selectable manner. The monitoring item selection section 601 may display the monitoring items hierarchically based on the type of the first sensor value. The monitoring item selection section 601 receives the selection of a monitoring item by the user. The monitoring item selection section 601 may receive the selection of only one monitoring item. FIG. 6 represents the monitoring item selected in the monitoring item selection section 601, using a shading. FIG. 6 illustrates an example of the monitoring item selection section 601 in which the monitoring item “Heater Power: In Deposition: Z1-BTM Temperature Power mean [%]” is selected.

The graph display section 602 displays the time-series graph of the first sensor value. The graph display section 602 may display the time-series graph of the first sensor value corresponding to the monitoring item selected in the monitoring item selection section 601. FIG. 6 illustrates an example of the graph display section 602 that displays the time-series graph of the monitoring item selected in the monitoring item selection section 601.

The graph display section 602 may include a range setting section 605 that sets a time range to be displayed in the time-series graph. The graph display section 602 may be a screen component that allows the setting of the start time and the end time of a sensor value to be displayed (e.g., a slider bar).

The data display section 603 displays information about the sensor data. The data display section 603 may be configured such that when a point of the sensor data in the graph display section 602 is selected, information about the selected sensor data is displayed. The data display section 603 may display items such as an apparatus, a start time, an end time, a start recipe, a start step, an end recipe, and an end step.

The correlation display button 604 is a button for starting the display of correlation data. When the user presses the correlation display button 604, the analysis screen is activated to select the second sensor value and the aggregation method thereof.

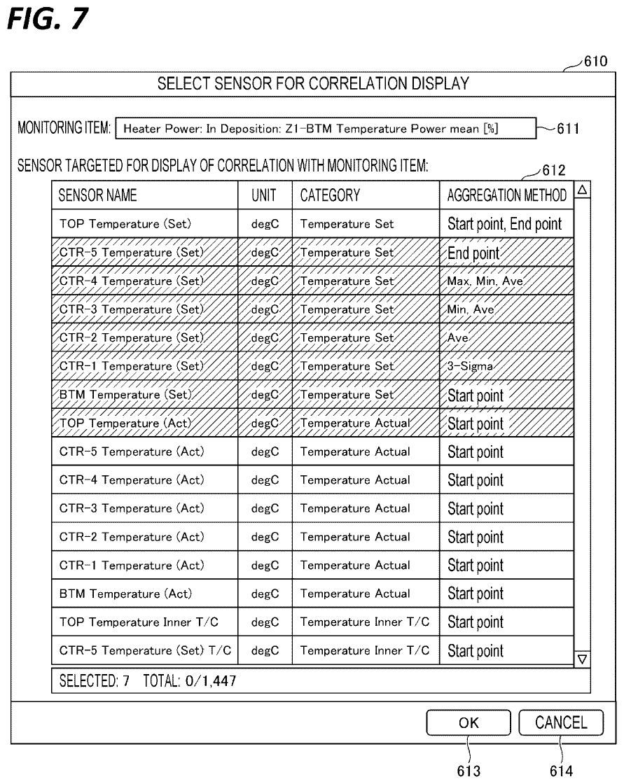

FIG. 7 is a view illustrating a second example of the analysis screen. FIG. 7 illustrates an example of the analysis screen 610 for selecting the second sensor value and the aggregation method thereof. As illustrated in FIG. 7, the analysis screen 610 includes a monitoring item display section 611, a sensor selection section 612, an OK button 613, and a cancel button 614.

The monitoring item display section 611 displays a monitoring item. The monitoring item display section 611 may display the monitoring item selected in the monitoring item selection section 601 of the analysis screen 600.

The sensor selection section 612 displays a list of second sensor values in a selectable manner. The sensor selection section 612 receives the selection of a second sensor value by the user. The sensor selection section 612 may receive the selection of a plurality of second sensor values. FIG. 7 represents the selected second sensor values using a shading. FIG. 7 illustrates an example of the sensor selection section 612 in which seven second sensor values are selected.

The sensor selection section 612 may display an aggregation method for each displayed second sensor value in a selectable manner. The sensor selection section 612 may receive the selection of a plurality of aggregation methods for each second sensor value. For example, FIG. 7 illustrates an example where the maximum value (Max), the minimum value (Min), and the average value (Ave) are selected as aggregation methods for “CTR-4 Temperature (Set).”

The OK button 613 is a button to display the correlation data. When the user presses the OK button 613, the analysis screen is activated to display the correlation data based on the second sensor values and the aggregation methods selected in the analysis screen 610.

The cancel button 614 is a button for stopping the display of the correlation data. When the user presses the cancel button 614, the analysis screen 610 is closed, and returns to the analysis screen 600.

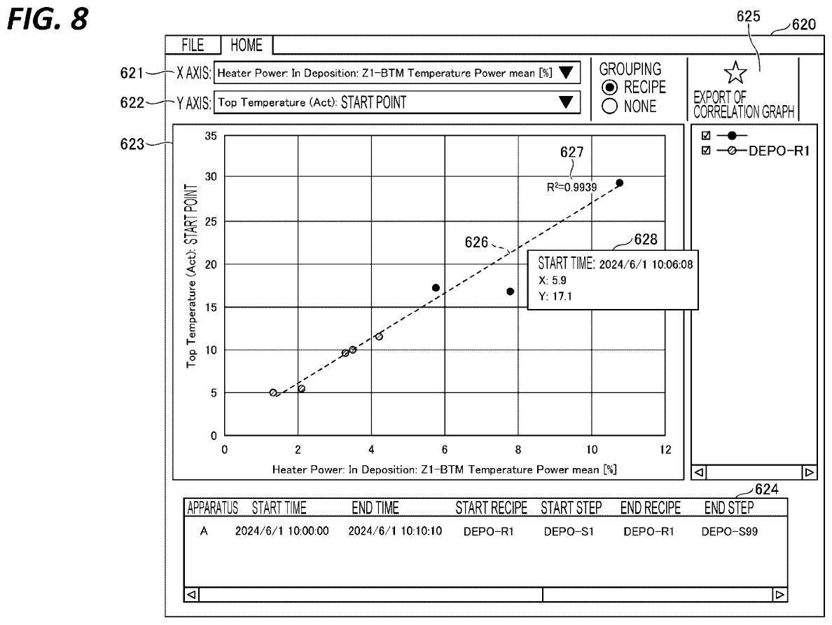

FIG. 8 illustrates a third example of the analysis screen. FIG. 8 illustrates an example of an analysis screen 620 that displays the correlation data between the first sensor value and the second sensor value. As illustrated in FIG. 8, the analysis screen 620 includes an X-axis selection section 621, a Y-axis selection section 622, a graph display section 623, a data display section 624, and an export button 625.

The X-axis selection section 621 receives the selection of the X axis of the correlation graph. The Y-axis selection section 622 receives the selection of the Y axis of the correlation graph. The X-axis selection section 621 may display the list of monitoring items displayed in the monitoring item selection section 601 of the analysis screen 600 as options for the X axis. The Y-axis selection section 622 may display the list of the second sensor values and the aggregation methods selected in the analysis screen 610 as options for the Y axis. The X-axis selection section 621 and the Y-axis selection section 622 may collectively display the monitoring items and the selected second sensor values as options for each axis. In this case, the X-axis selection section 621 and the Y-axis selection section 622 may be controlled such that the same option may not be selected.

The graph display section 623 displays a correlation graph between the sensor value selected in the X-axis selection section 621 and the sensor value selected in the Y-axis selection section 622. For example, FIG. 8 illustrates a correlation graph with the X axis representing “Heater Power: In Deposition: Z1-BTM Temperature Power mean [%],” which is an example of the monitoring item, and the Y axis representing “Top Temperature (Act): Start point,” which is an example of the second sensor value. The graph display section 623 may display an approximate straight line 626. The graph display section 623 may display a determination coefficient 627 (R²), which is an example of the evaluation index. The graph display section 623 may display detailed data 628 of each plot. The detailed data 628 may be displayed as, for example, a tooltip. That is, the detailed data 628 may be displayed as a pop-up near each plot when the plot is selected or when the cursor is superimposed on the plot.

The data display section 624 displays information about the sensor data. When a point of the sensor data in the graph display section 623 is selected, the data display section 624 may display information about the selected sensor data. The item displayed in the data display section 624 may be the same as that in the data display section 603 of the analysis screen 600.

The export button 625 is a button for exporting the correlation data. When the user presses the export button 625, the correlation data is output in a predetermined file format. The file format for exporting the correlation data may be, for example, the Comma Separated Value (CSV) format, the Excel (registered trademark) format, the Extensible Markup Language (XML) format, or the JavaScript Object Notation (JSON) format. The export button 625 may display a dialog window for selecting a storage location and a file format before exporting the correlation data.

### <Process Procedure>

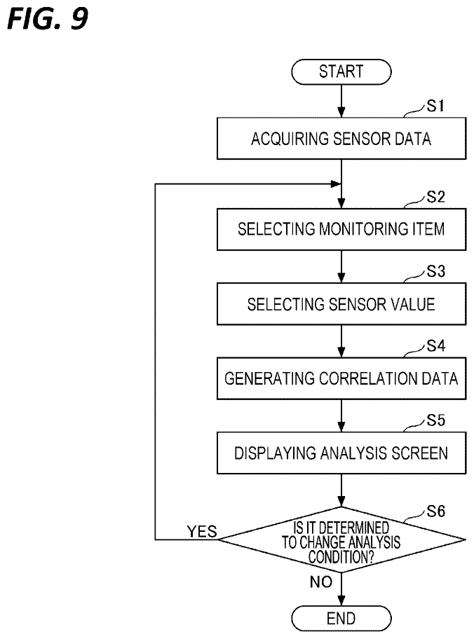

An analysis method performed by the substrate processing system 100 will be described with reference to FIG. 9. FIG. 9 is a flowchart illustrating an example of the analysis method.

In step S1, the acquisition unit 210 of the analysis apparatus 140 acquires sensor data generated in the substrate processing apparatus 120. The sensor data includes a plurality of time-series data representing a plurality of sensor values measured by a plurality of sensors provided in the substrate processing apparatus 120. The sensor data includes sensor values measured during the process execution period and sensor values measured outside the process execution period. The acquisition unit 210 sends the acquired sensor data to the selection unit 220.

In step S2, the selection unit 220 of the analysis apparatus 140 receives the sensor data from the acquisition unit 210. The selection unit 220 requests the display unit 240 to display the analysis screen. The display unit 240 displays the analysis screen on the display. The analysis screen displays the list of monitoring items in the selectable manner. The selection unit 220 selects sensor data including the first sensor value corresponding to the monitoring item designated by the user, according to the operation of the analysis screen by the user. The selection unit 220 sends the sensor data including the first sensor value to the generation unit 230.

In step S3, the selection unit 220 of the analysis apparatus 140 selects sensor data including the second sensor value designated by the user, according to the operation of the analysis screen by the user. Further, the selection unit 220 selects the aggregation method of the second sensor value designated by the user, according to the operation of the analysis screen by the user. The selection unit 220 sends information representing the sensor data including the second sensor value and the aggregation method of the second sensor value to the generation unit 230.

In step S4, the generation unit 230 of the analysis apparatus 140 receives the sensor data including the first sensor value, the sensor data including the second sensor value, and the information representing the aggregation method of the second sensor value, from the selection unit 220. The generation unit 230 calculates the representative value of the second sensor value based on the sensor data indicating the second sensor value and the aggregation method of the second sensor value. The generation unit 230 generates correlation data between the first sensor value and the second sensor value based on the sensor data including the first sensor value and the representative value of the second sensor value. The generation unit 230 sends the generated correlation data to the display unit 240.

In step S5, the display unit 240 of the analysis apparatus 140 receives the correlation data from the generation unit 230. The display nit 240 displays the correlation data on the analysis screen. The display unit 240 may display the correlation graph between the first sensor value and the second sensor value on the analysis screen. The display unit 240 may display the evaluation index based on the correlation graph, along with the correlation graph.

In step S6, the display unit 240 of the analysis apparatus 140 determines whether to change the analysis condition. For example, the display unit 240 determines whether an operation has been conducted to reselect at least one of the monitoring item, the second sensor value, and the aggregation method on the analysis screen. When it is determined that the operation has been conducted to reselect at least one of the monitoring item, the second sensor value, and the aggregation method, the display unit 240 determines to change the analysis condition. Meanwhile, when it is determined that the operation has not been conducted to reselect the sensor data, the second sensor value, and the aggregation method, the display unit 240 determines not to change the analysis condition.

When it is determined to change the analysis condition (YES), the display unit 240 returns the process to step S2. Meanwhile, when it is determined not to change the analysis condition (NO), the display unit 240 terminates the process of the analysis method.

When the process returns to step S2, the analysis apparatus 140 executes the process from step S2 to step S6 again, based on the monitoring item, the second sensor value, and the aggregation method selected on the analysis screen. Each time at least one of the monitoring item, the second sensor value, and the aggregation method is reselected, the analysis screen repeatedly displays the correlation data between the first sensor value and the second sensor value.

### Effects of Embodiment

The analysis apparatus 140 according to the present embodiment acquires the sensor data including the first sensor value and the second sensor value measured in the substrate processing apparatus 120 when the substrate processing apparatus 120 is not executing a process, and displays information representing the correlation between the first sensor value and the second sensor value. In an aspect, according to the present embodiment, the correlation of the plurality of sensor values measured when the process is not being executed is displayed, so that the state of the substrate processing apparatus when the process is not being executed may be analyzed.

The information representing the correlation may include the correlation graph between the first sensor value and the second sensor value. The information representing the correlation may include an approximate straight line of the correlation graph. In an aspect, according to the present embodiment, the correlation between the first sensor value and the second sensor value may be displayed in an easily understandable manner.

The analysis apparatus 140 may select the sensor data including the first sensor value that satisfies a predetermined condition. The analysis apparatus 140 may select the sensor data including the second sensor value designated by the user. The analysis apparatus 140 may display the information about the correlation between the second sensor value aggregated by the aggregation method designated by the user, and the first sensor value. In an aspect, according to the present embodiment, the correlation of the sensor values desired by the user may be analyzed using an arbitrary aggregation method.

The first sensor value may be the power of the heater that heats the processing container. The second sensor value may be the temperature in the processing container. In an aspect, according to the present embodiment, it is possible to analyze the relationship between the power of the heater and the temperature in the processing container outside the process execution period.

The first sensor value may be the flow rate of gas introduced into the transfer region where the workpieces are transferred to the processing container. The second sensor value may be the pressure in the transfer region. In an aspect, according to the present embodiment, it is possible to analyze the relationship between the flow rate of gas and the pressure in the transfer region outside the process execution period.

### OTHER EMBODIMENTS

The substrate processing apparatus, which performs the process including the substrate processing method of the present disclosure, is not limited to the heat treatment apparatus. The substrate processing apparatus may be applied to any of an atomic layer deposition (ALD) apparatus, capacitively coupled plasma (CCP), inductively coupled plasma (ICP), radial line slot antenna (RLSA), electron cyclotron resonance plasma (ECR), and helicon wave plasma (HWP).

Further, the substrate processing apparatus of the present disclosure may be applied to any of the apparatus that uses plasma and the apparatus that does not use plasma, as long as the apparatus performs a predetermined processing (e.g., film deposition and etching). Further, the substrate processing apparatus of the present disclosure may be applied to any of a single-wafer apparatus that processes substrates one by one, a batch apparatus that simultaneously processes a plurality of substrates, and a semi-batch apparatus that simultaneously processes a plurality of substrates fewer than the number of substrates processed in the batch apparatus.

The information processing apparatus and the substrate processing apparatus according to the embodiments described above are merely examples in all respects, and are not limited.

In an aspect, it is possible to analyze the state of the substrate processing apparatus when a process is not executed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. An information processing apparatus comprising:
acquisition circuitry configured to acquire sensor data including a first sensor value and a second sensor value measured in a substrate processing apparatus when the substrate processing apparatus is not executing a process; and
display circuitry configured to display information representing a correlation between the first sensor value and the second sensor value.

2. The information processing apparatus according to claim 1, wherein the information representing the correlation includes a correlation graph between the first sensor value and the second sensor value.

3. The information processing apparatus according to claim 2, wherein the information representing the correlation includes an approximate straight line of the correlation graph or a determination coefficient of the correlation graph.

4. The information processing apparatus according to claim 1, further comprising:
selection circuitry configured to select the sensor data including the first sensor value satisfying a predetermined condition.

5. The information processing apparatus according to claim 4, wherein the selection circuitry are configured to select the sensor data including the second sensor value designated by a user.

6. The information processing apparatus according to claim 5, wherein the display circuitry are configured to display information about a correlation between the second sensor value aggregated by an aggregation method designated by the user, and the first sensor value.

7. The information processing apparatus according to claim 1, wherein the first sensor value is a power of a heater that heats a processing container, and
the second sensor value is a temperature in the processing container.

8. The information processing apparatus according to claim 1, wherein the first sensor value is a flow rate of gas introduced into a transfer region where a workpiece is transferred to a processing container, and
the second sensor value is a pressure in the transfer region.

9. An information processing method comprising:
acquiring, by a computer, sensor data including a first sensor value and a second sensor value measured in a substrate processing apparatus when the substrate processing apparatus is not executing a process; and
displaying, by a computer, information representing a correlation between the first sensor value and the second sensor value.

10. A non-transitory computer-readable storage medium having stored therein a program that causes a computer to execute a process including:
acquiring sensor data including a first sensor value and a second sensor value measured in a substrate processing apparatus when the substrate processing apparatus is not executing a process; and
displaying information representing a correlation between the first sensor value and the second sensor value.
